(19) United States
(12) Patent Application Publication
(10) Pub. No.: US 2004/0183612 A1
(43) Pub. Date: Sep. 23, 2004

(54) Receiver set

(76) Inventor: Hiroshi Miyagi, Niigata (JP)

Correspondence Address: DELLETT AND WALTERS, P. O. BOX 2786, PORTLAND, OR, 97208-2786, US

(21) Appl. No.: 10/482,018

(22) PCT Filed: Jun. 24, 2002
(86) PCT No.: PCT/JP02/06268

(30) Foreign Application Priority Data
Jun. 29, 2001 (JP) 2001-198215

(51) Int. Cl. H03B 1/00

(52) U.S. Cl. 331/185

(57) ABSTRACT

A receiver for reducing the diffraction of a noise from a quarts oscillator. An analog circuit 20, an oscillator 30, a logic circuit 32, and a power source circuit 34 which constitute the receiver are formed in a one-chip component 10. The power source circuit 34 generates two kinds of action voltages and supplies a first action voltage to the analog circuit 20, and a second action voltage lower than the first one to the oscillator 30 and the logic circuit 32.

### TECHNICAL FIELD

The present invention relates to a receiver including an oscillator on which a quartz oscillator is externally mounted.

### BACKGROUND ART

A general receiver adopting a super-heterodyne method converts a frequency by using a mixing circuit after amplifying a modulated wave signal received via an antenna at a high frequency, and demodulates it after converting it into an intermediate-frequency signal having a predetermined frequency.

Particularly in recent years, there are an increasing number of receivers for performing reception frequency setting and various kinds of display control by a digital process, in which process an oscillator using a quartz oscillator for generating a highly accurate clock signal is used.

Incidentally, the oscillator on which a quartz oscillator is externally mounted has a problem that a basic component or a harmonic component of a unique oscillation frequency of the quartz oscillator sneaks on an antenna, a high-frequency amplifier circuit or a mixing circuit of the receiver mainly from a connection line thereof so as to generate noise. Particularly in recent years, there is the increasingly popular technique of forming most components including various analog circuits on a semiconductor substrate and make a one-chip component for the sake of miniaturization and cost reduction. Even in this case, the quartz oscillator must be an external component, and so there must exist a print wiring portion for connecting the one-chip component to the quartz oscillator. For this reason, the noise sneaks on the antenna side of the receiver from this wiring portion, resulting in suppression of sensitivity and deterioration of receiving quality.

### DISCLOSURE OF THE INVENTION

The present invention was created in view of these points, and an object thereof is to provide a receiver capable of reducing sneaking of noise from a quartz oscillator.

To solve the above-mentioned problem, the receiver according to the present invention has an analog circuit, an oscillator and a power supply circuit. The analog circuit performs a predetermined receiving process to a modulated wave signal received via an antenna. The oscillator has the quartz oscillator externally mounted thereon, and performs a predetermined oscillation. The power supply circuit supplies a first action voltage to the analog circuit, and also supplies to the oscillator a second action voltage lower than the first action voltage. As power of oscillation is in proportion to 1/(action voltage)², it is possible to set the action voltage lower than that of other analog circuits so as to reduce the noise sneaking from a wiring portion of the quartz oscillator.

It is desirable to integrally form the above-mentioned analog circuits and the components of the oscillator except the quartz oscillator on a semiconductor substrate. It is possible, by rendering them as a one-chip component having the circuits constituted on the semiconductor substrate, to reduce sneaking of the noise inside the chip. Therefore, it is possible to reduce the noise sneaking on the antenna side from the quartz oscillator connected as an external component by lowering the action voltage as mentioned above and reduce sneaking of other noise by rendering the components as one chip so as to significantly reduce various kinds of noise sneaking on the antenna side.

In the case where logic circuits connected to the oscillator are integrally formed on the semiconductor substrate, it is desirable that the above-mentioned power supply circuit supplies the second action voltage to the logic circuits as well as the oscillator. As signals inputted to the logic circuits are often 0V at a low level and are the action voltage at a high level, amplitude is so great that the sneaking of the noise via a power supply line and so on is apt to occur. Therefore, it is possible, as to such logic circuits, to simultaneously reduce the action voltage so as to reduce the sneaking of the noise through the inside of the chip.

It is also desirable to only reduce the action voltage as to the logic circuits performing a predetermined operation based on a clock signal generated by using the oscillator. Thus, it is feasible, with a few changes, to securely prevent the sneaking of the noise through the inside of the chip.

### BRIEF DESCRIPTION OF THE DRAWINGS

FIG. 1 is a diagram showing a configuration of an FM receiver according to the embodiment.

### BEST MODE FOR CARRYING OUT THE INVENTION

Hereafter, a receiver according to an embodiment of the present invention will be described in detail.

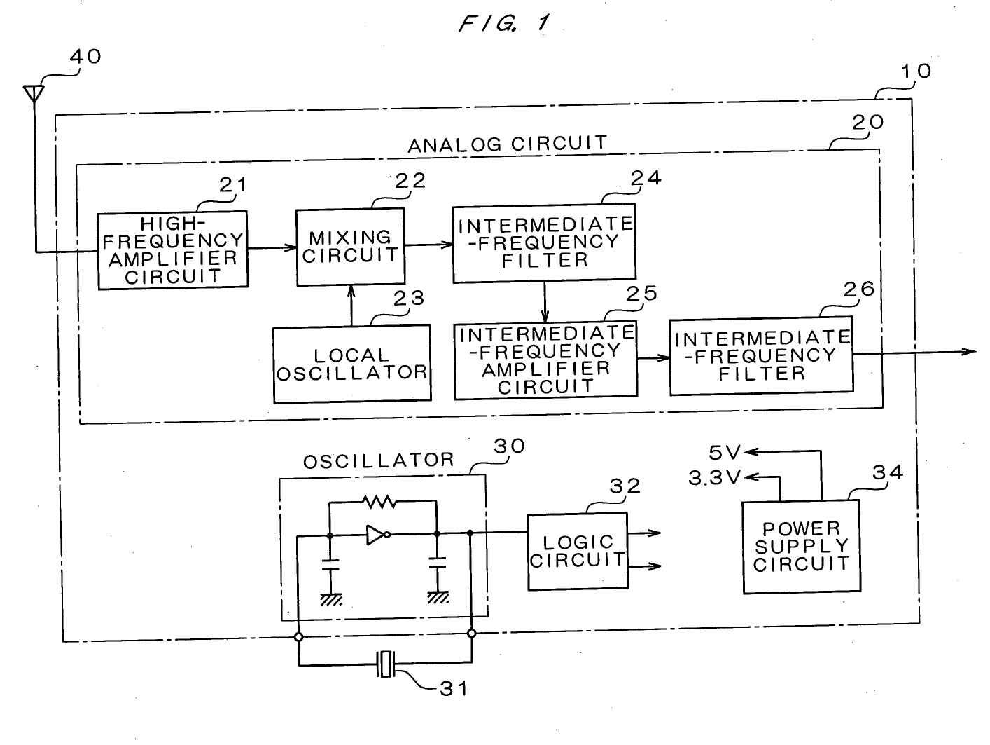

FIG. 1 is a diagram showing a configuration of an FM receiver according to this embodiment. The FM receiver shown in FIG. 1 is comprised of an analog circuit 20 formed as a one-chip component 10, an oscillator 30, a logic circuit 32 and a power supply circuit 34. The analog circuit 20 performs a predetermined receiving process to a modulated wave signal received via an antenna 40, and includes a high-frequency amplifier circuit 21, a mixing circuit 22, a local oscillator 23, intermediate-frequency filters 24, 26 and an intermediate-frequency amplifier circuit 25.

The analog circuit 20 may also include other circuits such as various demodulation process circuits according to the type of the receiver. As a main object of this embodiment is to reduce the sneaking of the noise from the oscillator 30 to the antenna 40 side, it is sufficient if the analog circuit 20 includes the high-frequency amplifier circuit 21, mixing circuit 22 and local oscillator 23. Therefore, the other circuits may also be connected to a subsequent stage to the one-chip component 10.

After amplifying the modulated wave signal received by the antenna 40 with the high-frequency amplifier circuit 21, a high-frequency signal is converted into an intermediate-frequency signal by mixing it with a local oscillation signal outputted from the local oscillator 23. The intermediate-frequency filters 24 and 26 are provided to a preceding stage and a subsequent stage to the intermediate-frequency amplifier circuit 25, and extract only a predetermined band component from an inputted intermediate-frequency signal. The intermediate-frequency amplifier circuit 25 amplifies some intermediate-frequency signals passing through the intermediate-frequency filters 24 and 26.

The oscillator 30 uses a quartz oscillator 31 connected as an external component as a resonant circuit, and generates a clock signal by performing oscillation at a unique oscillation frequency f₀ (in reality, a resonance frequency fᵣ which is a little higher) of the quartz oscillator 31. For instance, a general-purpose circuit using an inverter circuit may be used as the oscillator 30.

The logic circuit 32 performs various operations based on the clock signal outputted from the oscillator 30. The FM receiver also includes the logic circuits (a latch circuit, a shift register circuit and so on) which do not operate based on the clock signal. However, only the logic circuit 32 using the clock signal generated by the oscillator 30 is related to the sneaking of the noise from the oscillator 30. Other logic circuits are appropriately formed inside or outside the one-chip component 10 as required.

The power supply circuit 34 generates at least two types of action voltage, and supplies them to the analog circuit 20, oscillator 30 and logic circuit 32. To be more specific, the first action voltage (5V for instance) is supplied to the analog circuit 20. A second action voltage (3.3V for instance) lower than the first action voltage is supplied to the oscillator 30 and the logic circuit 32. It is desirable to render the second action voltage as the lowest voltage required to keep the oscillator 30 and the logic circuit 32 in operation.

In general, the power of oscillation is in proportion to 1/(action voltage)², and so it is possible, by setting the action voltage of the oscillator 30 lower than that of the analog circuit 20, to reduce the noise sneaking on the antenna 40 side from a wiring portion between the oscillator 30 and the quartz oscillator 31.

It is possible, by forming one-chip component 10 including the analog circuit 20 and oscillator 30 except the quartz oscillator 31, to reduce the sneaking of the noise inside the chip. Therefore, it is possible to reduce the noise sneaking on the antenna 40 side from the quartz oscillator 31 connected as an external component by reducing the action voltage as mentioned above and reduce the sneaking of other noise by rendering the components as one chip so as to significantly reduce various kinds of noise sneaking on the antenna 40 side.

It is also possible, by reducing the action voltage supplied to the logic circuit 32, to further reduce the sneaking of the noise through the inside of the chip. In general, the signals inputted to the logic circuits 32 are often 0V at a low level and are the action voltage at a high level, and thus amplitude is so great that the sneaking of the noise via a power supply line and so on is apt to occur. Therefore, it is possible, as to the logic circuits 32, to simultaneously reduce the action voltage so as to further reduce the sneaking of the noise through the inside of the chip.

The present invention is not limited to the above embodiment, but various modified embodiments are possible within the range of the gist thereof. For instance, according to the above embodiment, the power supply circuit 34 for generating two types of action voltage is formed inside the one-chip component 10. However, it may be provided outside the chip instead.

### INDUSTRIAL APPLICABILITY

As described above, according to the present invention, it is possible, by setting the action voltage of the oscillator lower than that of the other analog circuits, to reduce the noise sneaking from the wiring portion of the quartz oscillator.

1. A receiver having an analog circuit for performing a predetermined receiving process to a modulated wave signal received via an antenna, an oscillator having a quartz oscillator externally mounted thereon for performing predetermined oscillation, and a power supply circuit for supplying an action voltage to said analog circuit and said oscillator, characterized in that said power supply circuit supplies a first action voltage to said analog circuit, and also supplies to said oscillator a second action voltage lower than said first action voltage.

2. The receiver according to claim 1, characterized by integrally forming said analog circuit and components of said oscillator except said quartz oscillator on a semiconductor substrate.

3. The receiver according to claim 2, characterized in that said semiconductor substrate has a logic circuit connected to said oscillator integrally formed thereon, and said power supply circuit supplies a second action voltage to said logic circuits as well as said oscillator.

4. The receiver according to claim 3, characterized in that said logic circuit performs a predetermined operation based on a clock signal generated by using said oscillator.
